(19) United States
(12) Patent Application Publication
(10) Pub. No.: US 2002/0196865 A1
(43) Pub. Date: Dec. 26, 2002

(54) Cycle-by-cycle synchronous waveform shaping circuits based on time-domain superpostion and convolution

(75) Inventor: Wei Kwek Soh, Singapore (SG)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: The National University of Singapore, Singapore (SG)

(21) Appl. No.: 10/095,656

(22) Filed: Mar. 8, 2002

Related U.S. Application Data
(60) Provisional application No. 60/301,055, filed on Jun. 25, 2001.

(51) Int. Cl. H03C 3/00

(52) U.S. Cl. 375/303

(57) ABSTRACT

Cycle-by-cycle synchronous waveform shaping is provided for by filtering and combining of square and/or impulse shaped signals. Specifically, a plurality of first square shaped signals is generated and filtered using at least one first filter to produce at least one filtered signal. A plurality of second square shaped signals is generated and filtered using at least one second filter to produce at least one second filtered signal. The at least one first and at least one second filtered signals are combined to produce a continuous shaped waveform having a characteristic shape within each of a plurality of data periods defining a data rate. Alternatively, at least one impulse signal having a plurality of sinusoidal impulses each comprising a positive impulse and a negative impulse is generated. The at least one impulse signal is filtered using at least one filter to produce the continuous shaped waveform.

### CROSS-REFERENCES TO RELATED APPLICATIONS

This application claims priority from U.S. application Ser. No. 60/301,055, filed Jun. 25, 2001 entitled “Cycle-by-cycle Synchronous Waveform Shaping Circuits Based on Time-domain Superposition and Convolution.”

### STATEMENT AS TO RIGHTS TO INVENTIONS MADE UNDER FEDERALLY SPONSORED RESEARCH OR DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK.

NOT APPLICABLE

### BACKGROUND OF THE INVENTION

This invention relates generally to techniques for waveform shaping and more specifically to techniques for shaping individual cycles of a carrier waveform.

Waveform shaping at baseband has been an important process in the transmission of communication signals. Such waveform shaping is generally performed to obtain a more bandwidth efficient signal before modulation onto a carrier that allows transmission over a specific frequency band. Traditional modulation techniques for known modulation schemes such as Frequency Shift Keying (FSK) requires processing multiple cycles of the carrier signal in order for the receiver to lock effectively and detect a single symbol contained in the original signal. Such techniques also generally require the phase of the modulated signal to be continuous. The signal transmitted for a system employing such traditional techniques need not perform waveform shaping on a cycle-by-cycle basis, since symbol is spread over multiple cycles of the carrier waveform. However, when a communication signal represents each symbol using relatively few, or even just one cycle of the carrier waveform, shaping of individual cycles of the carrier waveform becomes necessary. Furthermore, it may still be required that the phase of the modulated signal be continuous.

### BRIEF SUMMARY OF THE INVENTION

Cycle-by-cycle synchronous waveform shaping is provided for by filtering and combining of square and/or impulse shaped signals. Specifically, a plurality of first square shaped signals is generated and filtered using at least one first filter to produce at least one filtered signal. A plurality of second square shaped signals is generated and filtered using at least one second filter to produce at least one second filtered signal. The at least one first and at least one second filtered signals are combined to produce a continuous shaped waveform having a characteristic shape within each of a plurality of data periods defining a data rate. In one embodiment, the continuous shaped waveform is a Frequency Shift Keying (FSK) signal having at least a first and a second frequency, wherein the first square shaped signals and the at least one first filter correspond to the first frequency, and wherein the second square shaped signals and the at least one second filter correspond to the second frequency.

Alternatively, at least one impulse signal having a plurality of sinusoidal impulses each comprising a positive impulse and a negative impulse is generated. The at least one impulse signal is filtered using at least one filter to produce the continuous shaped waveform. In one embodiment, at least one of the sinusoidal impulses is generated by differentially combining a square shaped signal with a delayed version of the square shaped signal.

### BRIEF DESCRIPTION OF THE DRAWINGS

FIG. 1 illustrates a Frequency Shift Keying (FSK) signal that can be generated using a particular technique for cycle-by-cycle synchronous waveform shaping.

FIG. 2 illustrates an embodiment of an FSK cycle-by-cycle synchronous waveform shaping circuit in accordance with the present invention.

FIG. 3 is a block diagram of an implementation of the FSK cycle-by-cycle synchronous waveform shaping circuit.

FIGS. 4A, 4B, 5A, and 5B are time domain plots representing the various filtered signals to be differentially combined in order to produce the desired FSK cycle-by-cycle synchronous waveform.

FIG. 6 is a time domain plot representing the desired FSK cycle-by-cycle synchronous waveform produced by the implementation shown in FIG. 3.

FIG. 7A is a functional diagram of the convolution process used in a second embodiment of the cycle-by-cycle synchronous waveform shaping circuit in accordance with the present invention.

FIGS. 7B and 7C illustrate examples of how the convolution process shown in FIG. 7A can be used to generate a Frequency Shift Keying (FSK) or a Binary Phase Shift Keying (BPSK) signal, respectively.

FIG. 8 is a block diagram of the second embodiment 800 of the cycle-by-cycle synchronous waveform shaping circuit producing a BPSK signal in accordance with the present invention.

FIG. 9 is a time domain plot representing the desired BPSK cycle-by-cycle synchronous waveform produced by the implementation shown in FIG. 8.

### DETAILED DESCRIPTION OF THE INVENTION

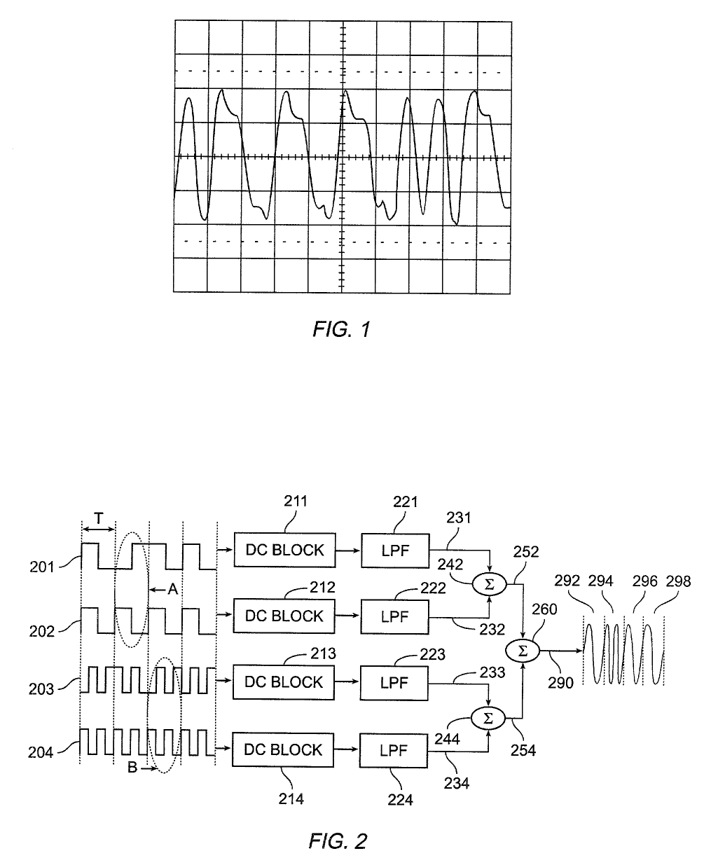

FIG. 1 illustrates a Frequency Shift Keying (FSK) signal that can be generated using a particular technique for cycle-by-cycle synchronous waveform shaping. This technique generates a FSK signal by sending a mixed square waveform through a low pass filter. Within each predefined frame, the mixed square waveform is either a lower frequency square wave or a higher frequency square wave. Thus, the filtered output represents a FSK signal. However, since the mixed square waveform contains both lower and higher frequency square waveforms, the single lowpass filter is not sufficient. This is because the harmonics of the lower frequency square waveforms are not removed. Therefore, the harmonics of the lower frequency square waveforms interfere with the higher frequency components of the output signal. As can be seen in FIG. 1, this approach generates a distorted FSK signal. More effective approaches to cycle-by-cycle synchronous waveform shaping are discussed below.

FIG. 2 is a high level functional block diagram of an illustrative embodiment 200 of a FSK cycle-by-cycle synchronous waveform shaping circuit in accordance with the present invention. The circuit 200 produces a FSK cycle-by-cycle synchronous waveform 290 having distinct data periods including data periods 292, 294, 296, and 298. Four synchronous digital signals 201, 202, 203, and 204 are provided as inputs to the circuit. The digital signals 201 and 202 each has a cycle of length T during which time the signal level transitions from a high level to a low level, or vice versa. Similarly, the digital signals 203 and 204 each has a cycle of length T/2 in which time the signal level transitions from a high level to a low level, or vice versa. Typically, the digital signals 201, 202, 203, and 204 can be generated by any of a number of conventional techniques such as digital logic, a processor, or the others implementations.

The digital signal 201 is passed through a digital block unit 211 and a low pass filter 221, to produce a filtered signal 231. The digital signal 202 is passed through a digital block unit 212 and a low pass filter 222, to produce a filtered signal 232. The digital signal 203 is passed through a digital block unit 213 and a low pass filter 223, to produce a filtered signal 233. Finally, the digital signal 204 is passed through a digital block unit 214 and a low pass filter 224, to produce a filtered signal 234. The digital block units 211, 212, 213, and 214 each removes the DC component from each of the digital signals 201, 202, 203, and 204, respectively. The filtered signals 231 and 232 combine at a combiner 242 to form a first combined signal 252. The filtered signals 233 and 234 combine at a combiner 244 to form a second combined signal 254.

The first combined signal 252 might include regions in the signal a “null”. Consider for example, the region “A” of the input signals 201, 202. The figure shows that at the region “A”, there is a 180° phase difference between the digital signals 201 and 202. Consequently, the filtered signals 231 and 232, which correspond to the digital signals 201 and 202, significantly cancel each other in the region “A” when they are combined at the combiner 242. Thus, the first combined signal 252 has an a null signal at a region that corresponds to the region “A”. On the other hand, in the same region of the combined signal 254 that corresponds to region “A”, the signal is amplified. That is, in region “A”, there is a 0° phase difference between the digital signals 203 and 204. Thus, the filtered signals 233 and 234, which correspond to the digital signals 203 and 204, significantly add to each other in the region “A” when they are combined at the combiner 244.

Similarly, the second combined signal 254 is effectively a null signal in certain other regions. For example, in an illustrative region 37 B,” there is ideally a 180 degree phase difference between the digital signals 203 and 204. Consequently, the filtered signals 233 and 234, which correspond to the digital signals 203 and 204, significantly cancel each other in the region “B” when they are combined at the combiner 244. Thus, the second combined signal 254 is effectively a null signal within the region “B.” On the other hand, in the same region, the combined signal 252 is an amplified signal. That is, in region “B,” there is ideally a 0 degree phase difference between the digital signals 201 and 202. Thus, the filtered signals 231 and 232, which correspond to the digital signals 201 and 202, significantly add to each other in the region “B” when they are combined at the combiner 242.

The first and second combined signal 252 and 254 are combined to each other at a combiner 260 to form the FSK cycle-by-cycle synchronous waveform 290 suitable for transmission. The waveform 290 has distinct data periods including data periods 292, 294, 296, and 298. Note that data periods 292, 294, and 298 correspond to regions in which the first combined signal 252 contributes a signal having a cycle of length T, and the second combined signal 254 contributes an effectively null signal. Also note that data period 296 corresponds to a region in which the second combined signal 254 contributes a signal having two cycles of length T/2 each, and the first combined signal 252 contributes an effectively null signal.

It can be appreciated from FIG. 2 that the principle of superposition provides an alternate configuration whereby the digital signals 201-204 are combined to produce an intermediate digital signal, prior to performing the filtering. The intermediate digital signal can then be DC blocked to remove a DC component if necessary, and then low pass filtered using a single appropriately designed low pass filter.

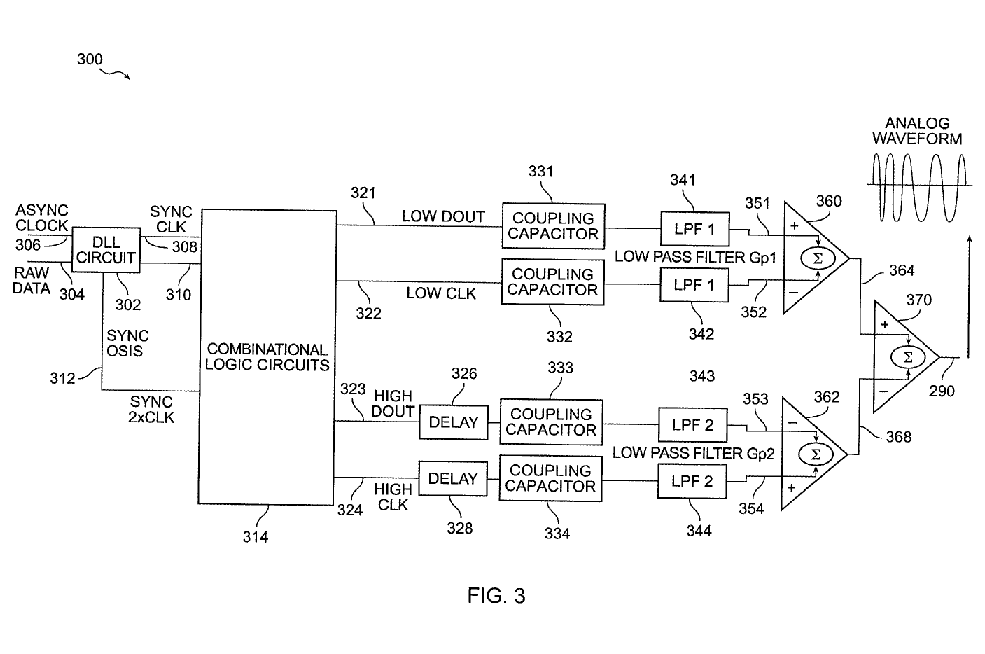

FIG. 3 is a block diagram 300 of an implementation of the FSK cycle-by-cycle synchronous waveform shaping circuit 200. This implementation produces one cycle of a signal with frequency f₀ (one cycle having a 1/f₀ period) to represent a bit “1” and two cycles of a signal with frequency f₁ (two cycles each having 1/f₁, period) to represent a bit “0.” Here, f₁, is a frequency that is twice f₀.

A Delayed Lock Loop (DLL) circuit 302 receives a raw data signal 304 and an asynchronous clock signal 306 and performs the function of locking to the timing of the incoming raw data signal 304. The DLL circuit 302 outputs a Sync Clk signal 308, a Sync Data signal 310, and a 2× Sync Clk signal 312. The Sync Clk signal 308 has a frequency equivalent to the data rate of the Sync Data signal 310. The 2× Sync Clk signal 312 has a frequency twice the data rate of the Sync Data signal 310. Both clock signals 308 and 312 are synchronous with the Sync Data signal 310.

The Sync Clk signal 308, Sync Data signal 310, and 2× Sync Clk signal 312 are input to a Combinational Logic Circuit 314, which produces a Low Dout signal 321, a Low Clk signal 322, a High Dout signal 323, and a High Clk signal 324. The Low Dout signal 321 passes through a coupling capacitor 331 and a low pass filter 341 to form a filtered signal 351. The Low Clk signal 322 passes through a coupling capacitor 332 and a low pass filter 342 to form a filtered signal 352. The High Dout signal 323 passes through a delay block 326, a coupling capacitor 333, and a low pass filter 343 to form a filtered signal 353. The High Clk signal 324 passes through a delay block 328, a coupling capacitor 334, and a low pass filter 344 to form a filtered signal 354.

Note that the Low Dout signal 321 and the Low Clk signal 322 together represent cycles of the lower frequency f₀ signal used to indicate the bit “1”s. However, in this implementation, the Low Dout signal 321 alone carries the information relating to the location of the bit “1”s. The Low Clk signal 322 is merely a clock signal synchronous with the Low Dout signal 321. Nevertheless, the Low Clk signal 322 is used in combination with the Low Dout signal 321 to ensure that the time span of a non-zero value on either digital signal 321 or 322 will be at most 2T_{L}, where T_{L} is the time span between two possible transitions on either signal 321 or 322.

Similarly, the High Dout signal 323 and the High Clk signal 324 together represent cycles of the higher frequency f₁ signal used to indicate the bit “0”s. The High Dout signal 323 alone carries the information relating to the location of the bit “0”s. The High Clk signal 324 is merely a clock signal synchronous with the High Dout signal 323. The two signals used in combination ensure that the time span of a non-zero value on either digital signal 323 or 324 will be at most 2T_{H}, where T_{H} is the time span between two possible transitions on either signal 323 or 324.

Also note that the low pass filters 341 and 342 together form a low pass filter group 1 in which each filter has a cut-off frequency corresponding to the pulse frequency ½T_{L} of the digital signals (Low Dout signal 321 and Low Clk signal 322) they serve. The low pass filters 343 and 344 together form a low pass filter group 2 in which each filter has a cut-off frequency corresponding to the pulse frequency ½T_{H} of the digital signals (High Dout signal 323 and High Clk signal 324) they serve. The low pass filters 321, 322, 323, and 324 thus appropriately reduce the harmonics in the various signals being filtered. The low pass filters 321,322, 323, and 324 can be implemented as analog infinite response impulse response filters. Any kind of appropriate conventionally known filter can be used, including Butterworth filters, Bessel filters, and so on. In a particular embodiment of the invention, for example, the low pass filters are implemented as Gaussian filters, which are known to contribute less distortion in neighboring pulses of the signals being filtered.

Delay blocks 326 and 328 are used to add delay to the High Dout signal 323 and High Clk signal 324 in order to compensate for the difference between the delay associated with low pass filter group 1 and the delay associated with low pass filter group 2. The delay blocks 326 and 328 can be implemented as adjustable digital delays, a long transmission path or wire, or others.

Referring again to FIG. 3, the filtered signals 351 and 352 are differentially combined at a differential combiner 360 to produce a first differentially combined signal 364. Within each region representing a data period associated with a bit “0,” the filtered signals 351 and 352 significantly cancel each other at the differential combiner 360, and the first differentially combined signal 364 is effectively a null signal within the region. Similarly, the filtered signals 353 and 354 are differentially combined at a differential combiner 362 to produce a second differentially combined signal 368. Within each region representing a data period associated with a bit “1,” the filtered signals 353 and 354 significantly cancel each other at the differential combiner 362, and the second differentially combined signal 368 is effectively a null signal within that region.

The first and second differentially combined signals 364 and 368 are differentially combined to each other at a differential combiner 370 to produce the desired FSK cycle-by-cycle synchronous waveform 290 that is suitable for transmission. Note that differential combiners 360, 362, and 370 are used because the various signals are transmitted in a differential mode, which allows improvements in noise rejection and formation of sinusoidal waveforms. Differential signaling in this embodiment is achieved by using the combinatorial logic circuits 314 to appropriately control the polarity of the Low Dout signal 321, the Low Clk signal 322, the High Dout signal 323, and the High Clk signal 324.

It should be noted that while FIG. 3 illustrates the production of an FSK cycle-by-cycle synchronous waveform, a similar implementation can be used to generate a Binary Phase Shift Keying (BPSK) or another type of Phase Shift Keying (PSK) cycle-by-cycle synchronous waveform by generating digital signals of different phases and filtering and/or combining such digital signals.

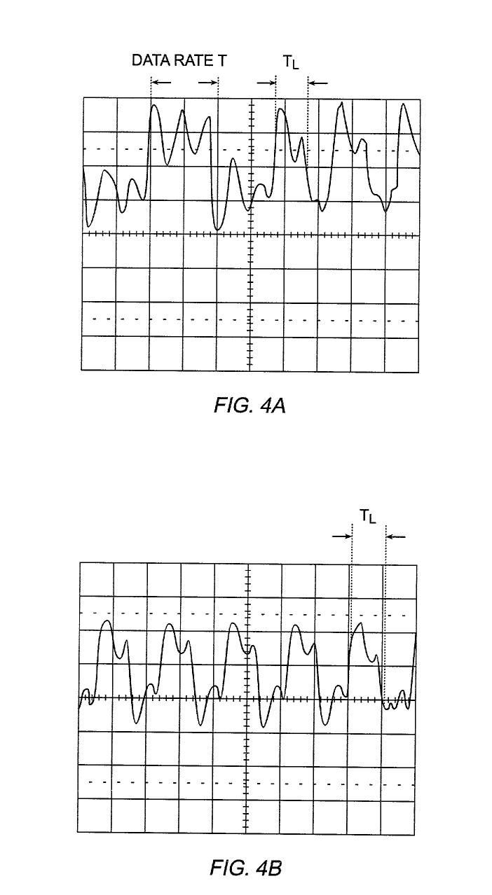

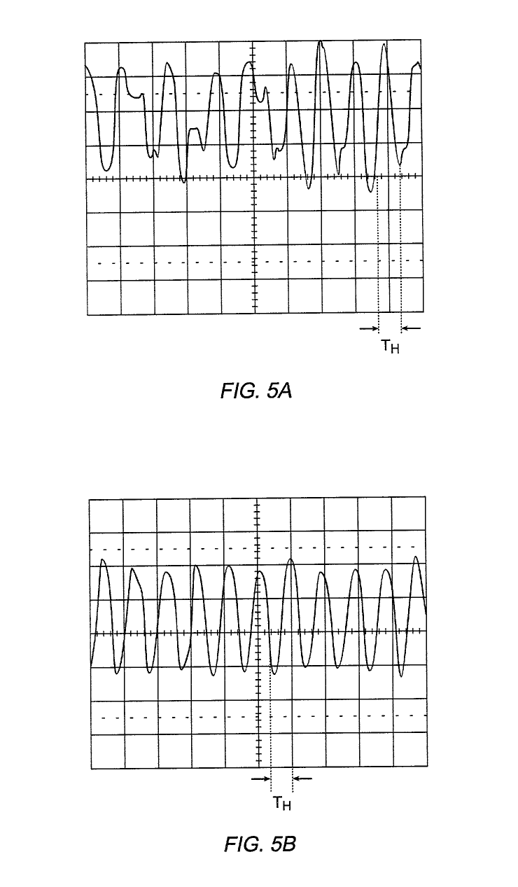

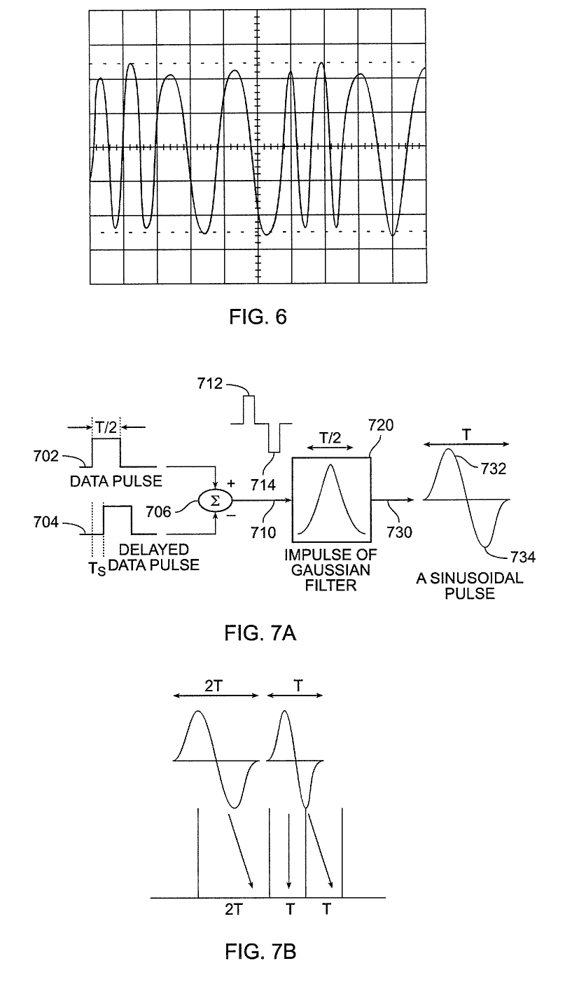

FIGS. 4A, 4B, 5A, and 5B are time domain plots representing the various filtered signals to be differentially combined in order to produce the desired FSK cycle-by-cycle synchronous waveform 290. FIG. 4A and 4B represent the filtered signals 351 and 352, respectively. Note that these two signals are characterized by the time span T_{L}. FIGS. 5A and 5B represent the filtered signals 353 and 354, respectively. Note that these two signals are characterized by the time span T_{H}. FIG. 6 is a time domain plot representing the desired FSK cycle-by-cycle synchronous waveform 290 produced by the circuit shown in FIG. 3.

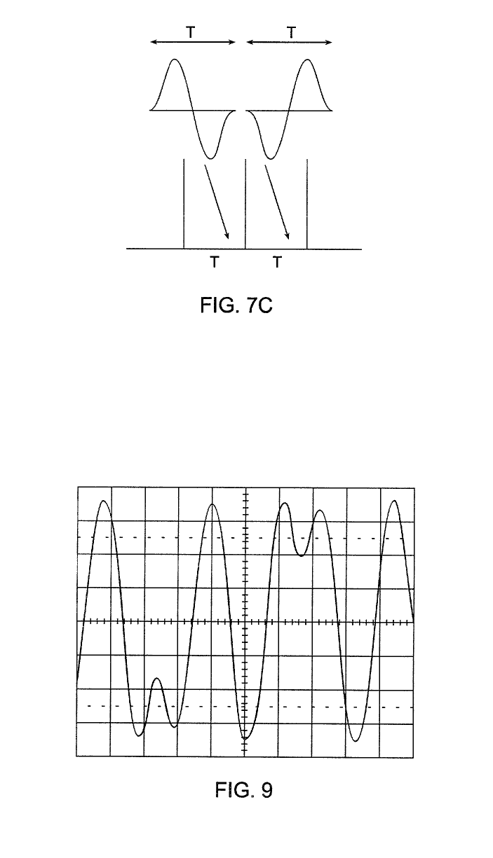

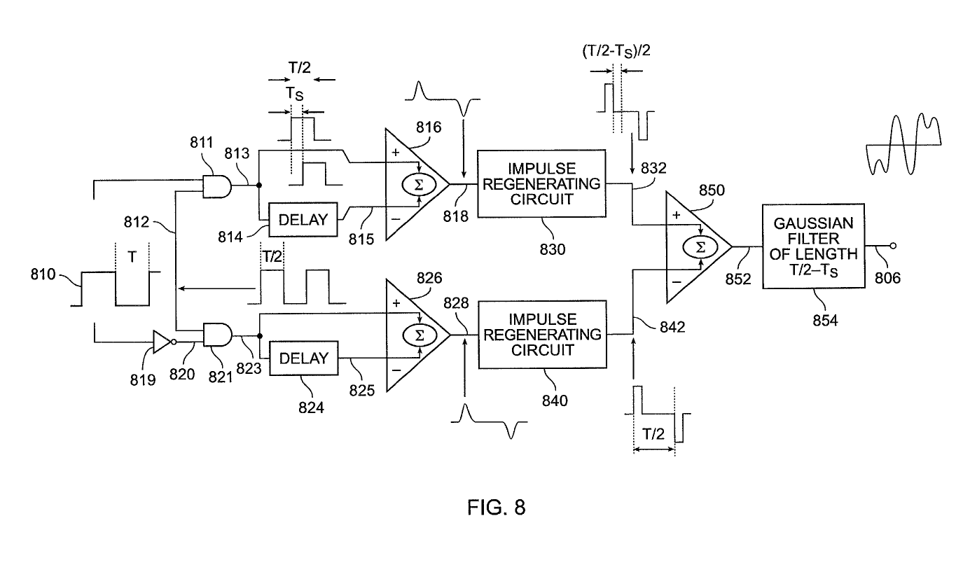

FIG. 7A is a functional diagram of the convolution process used in a second embodiment 800 (FIG. 8) of the cycle-by-cycle synchronous waveform shaping circuit in accordance with the present invention. A data pulse 702 and a delayed data pulse 704 are differentially combined at a differential combiner 706 to produce an impulse pair 710 having a positive impulse 712 and a negative impulse 714.

The delayed data pulse 704 is delayed in time by a precise amount relative to the data pulse 702 but otherwise resembles the data pulse 702. The data pulse 702 and delayed data pulse 704 can be generated by digital logic, a processor, or the others implementations. The data pulse 702 and the delayed data pulse 704 overlap in a period of length T/2−Ts. When differentially combined, the data pulse 702 and the delayed data pulse 704 cancel each other in this overlapping period, and non-overlapping portions of the pulses 702 and 704 form a positive impulse 712 and a negative impulses 714 of an impulse pair 710.

The impulse pair 710 is convolved with a Gaussian filter 720 in the time domain to produce a sinusoidal pulse 730 having a positive half cycle 732 and a negative half cycle 734. The positive impulse 712 of the impulse pair 710 produces the positive half cycle 732, which resembles the impulse response of the Gaussian filter 720. The negative impulse 714 of the impulse pair 710 produces the negative half cycle 734, which resembles the negative of the impulse response of the Gaussian filter 720. The Gaussian filter 720 has a compact impulse response and a less oscillatory nature compared to other filter designs. The Gaussian filter 720 can also be realized in the form of a LC circuit. However, other types of filters such as Butterworth filters and Bessel filters may also be used.

FIGS. 7B and 7C illustrate examples of how the convolution process shown in FIG. 7A can be used to generate a Frequency Shift Keying (FSK) or a Binary Phase Shift Keying (BPSK) signal, respectively. The convolution process shown in FIG. 7A is highly controllable and precise in generating a sinusoidal pulse at a specified time. By generating and superpositioning appropriate sinusoidal pulses at particular positions in time, appropriate data modulated signals such as FSK and BPSK signals can be produced. FIG. 7B illustrates that a portion of an FSK signal can be produced by concatenating a sinusoidal impulse having a length of 2T with two sinusoidal impulses each having a length of T. FIG. 7C illustrates that a portion of a BPSK signal can be produced by concatenating a sinusoidal impulse having a length of T with another sinusoidal impulse having a length of T but being inverse in amplitude.

FIG. 8 is a block diagram of the second embodiment 800 of the cycle-by-cycle synchronous waveform shaping circuit producing a BPSK signal in accordance with the present invention. Here, two distinct sinusoidal pulses 802 and 804 are generated at particular positions in time and differentially combined to form one portion of a desired BPSK cycle-by-cycle synchronous waveform 806. Although only the sinusoidal pulses 802 and 804 are shown in FIG. 8, it should be understood that other sinusoidal pulses preceding, following, or even overlapping with sinusoidal pulses 802 and 804 are also differentially combined to form other portions of the BPSK cycle-by-cycle synchronous waveform 806.

Referring to FIG. 8, a digital signal 810 containing data pulses of length T is generated and provided to the circuit 800. An AND function block 811 receives the digital signal 810 and a clock signal 812, which has pulses of length T/2 and is synchronous with the digital signal 810. The AND function block 811 outputs a half-cycle signal 813. In this manner, each data pulse in digital signal 810 representing a bit ‘1’ (or bit ‘high’) is extracted and reduced to half duty cycle, producing the half-cycle signal 813. A delay block 814 receives the half-cycle signal 813, introduces a delay of Tₛ, and produces a delayed half-cycle signal 815. The half-cycle signal 813 and the delayed half-cycle signal 815 are differentially combined at a differential combiner 816 to produce an impulse pair signal 818.

The digital signal 810 is inverted at an inverter 819, producing an inverted digital signal 820. An AND function block 821 receives the inverted digital signal 820 and the clock signal 812, which has pulses of length T/2 and is synchronous with the inverted digital signal 820. The AND function block 811 outputs a half-cycle signal 823. In this manner, each data pulse in digital signal 810 representing a bit ‘0’ (or bit ‘low’) is extracted and reduced to half duty cycle, producing the half-cycle signal 823. A delay block 824 receives the half-cycle signal 823 , introduces a delay of Tₛ, and produces a delayed half-cycle signal 825. The half-cycle signal 823 and the delayed half-cycle signal 825 are differentially combined at a differential combiner 826 to produce an impulse pair signal 828.

An impulse regenerating circuit 830 receives the impulse pair signal 818 and produces a regenerated impulse pair signal 832. Similarly, an impulse regenerating circuit 840 receives the impulse pair signal 828 and produces a regenerated impulse pair signal 842. Under certain conditions, the impulse pair signals 818 and 828 may not have proper signal level and/or form to be adequate impulse signals. For example, a low slew rate associated with the digital signals 813, 815, 823, and 825 caused by digital data buffers supplying these signals may result in a “smearing” of the positive pulses and negative pulses of the impulse pair signals 818 and 828. These positive and negative pulses could thus lack proper signal level and/or form. The impulse regenerating circuits 830 and 840 corrects such problems by adjusting the signal levels and/or other characteristics of the regenerated impulse pair signals 832 and 842 such that they provide adequate impulse signals.

A differential combiner 854 receives the regenerated impulse pair signals 832 and 842 and produces a combined regenerated impulse pair signal 852. A Gaussian filter 854 of length T/2−Tₛ receives the combined regenerated impulse pair signal 852 and produces the BPSK cycle-by-cycle synchronous waveform 806. Alternatively, the regenerated impulse pair signal 832 and the regenerated impulse pair signal 842 can be separately filtered and then differentially combined. In such case, two Gaussian filter are needed. FIG. 9 is a time domain plot representing the desired BPSK cycle-by-cycle synchronous waveform produced by the implementation shown in FIG. 8.

It should be noted that while FIG. 8 illustrates the production of a BPSK cycle-by-cycle synchronous waveform, a similar implementation can be used to generate an FSK cycle-by-cycle synchronous waveform by generating impulse pairs corresponding to different frequencies and filtering and/or combining such impulse pairs.

Although the present invention has been described in terms of specific embodiments, it should be apparent to those skilled in the art that the scope of the present invention is not limited to the described specific embodiments.

The specification and drawings are, accordingly, to be regarded in an illustrative rather than a restrictive sense. It will, however, be evident that additions, subtractions, substitutions, and other modifications may be made without departing from the broader spirit and scope of the invention as set forth in the claims.

What is claimed is:

1. A method for generating a continuous shaped waveform for transmission in a communication system, the method comprising:
generating a plurality of first square shaped signals;
filtering said first square shaped signals to produce at least one filtered signal;
generating a plurality of second square shaped signals;
filtering said second square shaped signals to produce at least one second filtered signal; and
combining said at least one first and at least one second filtered signals to produce said continuous shaped waveform, said continuous shaped waveform having a characteristic shape within each of a plurality of data periods defining a data rate.

2. The method of claim 1 wherein said first filtered signals significantly cancel one another in at least one of said data periods.

3. The method of claim 2 wherein said second filtered signals significantly add to one another in said at least one of said data periods.

4. The method of claim 1 wherein said continuous shaped waveform is a Frequency Shift Keying (FSK) signal having at least a first frequency component and a second frequency component, wherein said first frequency component is based on said first square shaped signals, and wherein second frequency component is based on said second square shaped signals.

5. The method of claim 1 wherein said first and second square shaped signals are digital signals.

6. The method of claim 1 wherein said first and second square shaped signals are synchronous signals.

7. The method of claim 1 further comprising a step of removing DC component from said first and second square shaped signals.

8. The method of claim 1 further comprising the steps of:
before said step for filtering said first square shaped signals, combining said first square shaped signals; and
before said step for filtering said second square shaped signals, combining said second square shaped signals.

9. The method of claim 8 wherein said first square shaped signals significantly cancel one another in at least one of said data periods.

10. The method of claim 9 wherein said second square shaped signals significantly add to one another in said at least one of said data periods.

11. The method of claim 1 wherein said at least one first filtered signal and said at least one second filtered signal are combined differentially.

12. The method of claim 8 wherein said first square shaped signals are combined differentially and said second square shaped signals are combined differentially.

13. The method of claim 1 wherein said filtering said first square shaped signals includes performing one of: a Gaussian-type filtering, a Bessel-type filtering, and a Butterworth-type filtering operation.

14. The method of claim 1 wherein said continuous shaped waveform is a Phase Shift Keying (PSK) signal.

15. The method of claim 14 wherein said PSK signal is a Binary Phase Shift Keying (BPSK) signal.

16. A system for generating a continuous shaped waveform suitable for transmission in a communication system, the system comprising:
means for generating a plurality of first pulses;
means for filtering said first pulses to produce at least one filtered signal;
means for generating a plurality of second pulses;
means for filtering said second pulses to produce at least one second filtered signal; and
means for combining said at least one first and at least one second filtered signals to produce said continuous shaped waveform, said waveform having a characteristic shape within each of a plurality of data periods defining a data rate.

17. A method for generating a continuous shaped waveform suitable for transmission in a communication system, the method comprising:
generating at least one impulse signal having a plurality of sinusoidal impulses, each said sinusoidal impulse comprising a positive impulse and a negative impulse; and
filtering said at least one impulse signal to produce said continuous shaped waveform, said waveform having a characteristic shape within each of a plurality of data periods defining a data rate.

18. The method of claim 17 further comprising a step of combining said impulse signals before said filtering step.

19. The method of claim 17 further comprising a step of combining said impulse signals after said filtering step.

20. The method of 17 wherein at least one of said sinusoidal impulses is generated by differentially combining a square shaped signal with a delayed version of said square shaped signal.

21. The method of claim 20 wherein said square shaped signal is a digital signal.

22. The method of claim 20 wherein said square shaped signal is a synchronous signal.

23. The method of 18 or 19 wherein said impulse signals are differentially combined.

24. The method of claim 17 wherein said filtering in accordance with one of: a Gaussian filter, a Bessel filter, and a Butterworth filter.

25. The method of claim 17 wherein said continuous shaped waveform is a Phase Shift Keying (PSK) signal.

26. The method of claim 27 wherein said PSK signal is a Binary Phase Shift Keying (BPSK) signal.

27. The method of claim 17 wherein said continuous shaped waveform is a Frequency Shift Keying (FSK) signal.

28. A system for generating a continuous shaped waveform suitable for transmission in a communication system, the system comprising:
means for generating at least one impulse signal having a plurality of sinusoidal impulses, each said sinusoidal impulse comprising a positive impulse and a negative impulse; and
means for filtering said at least one impulse signal using at least one filter to produce said continuous shaped waveform, said waveform having a characteristic shape within each of a plurality of data periods defining a data rate.
